(19) United States
(12) Patent Application Publication
(10) Pub. No.: US 2013/0224919 A1
(43) Pub. Date: Aug. 29, 2013

(54) METHOD FOR MAKING GATE-OXIDE WITH STEP-GRADED THICKNESS IN TRENCHED DMOS DEVICE FOR REDUCED GATE-TO-DRAIN CAPACITANCE

(71) Applicants: Yongping Ding, San Jose, CA (US); Sik Lui, Sunnyvale, CA (US); Anup Bhalla, Santa Clara, CA (US)

(72) Inventors: Yongping Ding, San Jose, CA (US); Sik Lui, Sunnyvale, CA (US); Anup Bhalla, Santa Clara, CA (US)

(21) Appl. No.: 13/406,814

(22) Filed: Feb. 28, 2012

(51) Int. Cl. H01L 21/336

(52) U.S. Cl. 438/270; 257/E21.419

(57) ABSTRACT

A method for making gate-oxide with step-graded thickness (S-G GOX) in a trenched DMOS device is proposed. First, a substrate is provided and a silicon oxide-silicon nitride-silicon oxide (ONO) protective composite layer is formed atop. Second, an upper interim trench (UIT), an upper trench protection wall (UTPW) and a lower interim trench (LIT) are created into the substrate. Third, the substrate material surrounding the LIT is shaped and oxidized into a desired thick-oxide-layer of thickness T1 and depth D1. Fourth, previously formed UTPW is stripped off from the device in progress, then a thin-gate-oxide of thickness T2 where T2<T1 is formed on the vertical surface of the UIT. Fifth, the UIT and LIT are filled with polysilicon then etched back into a polysilicon layer till its top surface defines a desired thin-gate-oxide depth D2.

### CROSS REFERENCE TO RELATED APPLICATIONS

This application is related to the following patent documents:

Title: “SHIELDED GATE TRENCH (SGT) MOSFET DEVICES AND MANUFACTURING PROCESSES”, U.S. Pat. No. 7,633,119, granted on Dec. 15, 2009, by Bhalla et al, hereinafter referred to as U.S. Pat. No. 7,633,119.

Title: “Device structure and manufacturing method using HDP deposited source-body implant block”, US Patent Application publication 20080265289 (application Ser. No. 11/796,985), published on Oct. 30, 2008, by Bhalla et al, hereinafter referred to as US 20080265289.

Title: “Double gate-oxide for reducing gate-drain capacitance in trenched DMOS with high-dopant concentration buried-region under trenched gate”, U.S. Pat. No. 6,262,453, granted on Jul. 17, 2001, by Hshieh, hereinafter referred to as U.S. Pat. No. 6,262,453.

The above contents are incorporated herein by reference for any and all purpose.

### FIELD OF INVENTION

This invention relates generally to the field of semiconductor device structure and fabrication. More specifically, the present invention is directed to manufacturing method to form a trenched DMOS Device with reduced gate-to-drain capacitance.

### BACKGROUND OF THE INVENTION

Numerous prior arts exist for the structure & method of making trenched DMOS devices with a variety of improved gate structures for correspondingly improved device properties such as reduced gate-to-drain capacitance and maintenance of a high drain-source breakdown voltage.

As a first example, FIG. 1 illustrates an MOSFET device including a shielded gate trench (SGT) structure of U.S. Pat. No. 7,633,119. The trenched MOSFET device is supported on a substrate 105 formed with an epitaxial layer 110 having uniformed doping concentration of a first conductivity type, e.g., P-type dopant. The trenched MOSFET device includes a shielded gate trench structure. The SGT structure includes a bottom-shielding electrode 130 insulated from and disposed below a trenched gate 150. The bottom SGT structure 130 filled with a polysilicon therein is provided to shield the trenched gate 150 from the drain disposed below trench bottom. An insulation layer 120 separated the bottom-shielding electrode 130 from the trenched gate 150. The trenched gate 150 includes polysilicon filling in a trench surrounded with a gate insulation layer covering the trench walls. A body region 160 that is doped with a dopant of second conductivity type, e.g., P-type dopant, extends between the trenched gates 150. The P-body regions 160 encompassing a source region 170 doped with the dopant of first conductivity, e.g., N+ dopant. The source regions 170 are formed near the top surface of the epitaxial layer surrounding the trenched gates 150. On the top surface of the semiconductor substrate is also an insulation layer 180. The contact openings 185 and 195 are opened through the insulation layer 180 to contact the source metal layer 190. The bottom-shielding electrode 130 is electrically connected to the source metal 190 through the trenched source-connecting electrode 140. The trenched source-connecting electrode 140 is electrically connected to the bottom-shielding electrode 130 through the interconnected trenches that extend between the MOSFET cells. The trenched source connecting electrode 140 may be extrude beyond the top surface of body region 160 and source region 170 to increase the area of contact.

As well known in the art, to take full advantage of the source electrode in a SGT device structure of the type described above in FIG. 1, either a graded doping concentration of the epitaxial layer with uniform thickness of the dielectric material, i.e. insulation layer, lining the bottom and the sidewall of the gate trench or, otherwise, a uniform doping concentration of the epitaxial layer with graded thickness of the dielectric material lining the bottom and the sidewall of the gate trench is implemented. However, for the case of a uniform dielectric thickness, the device will achieve better on-resistance (Rdson)/breakdown voltage (BVDss) figure of merits (FOM) under condition of linearly graded Epi doping concentration than the condition of a uniform Epi doping concentration. On the other hand, when the Epi doping concentration is uniform (for easy Epi fabrication), the device will achieve better Rdson/BVDss figure of merits (FOM) under condition of graded dielectric thickness than the condition of uniform dielectric thickness.

As a second example, FIG. 2 illustrates a power semiconductor device from:
Title: “Power semiconductor devices having improved high frequency switching and breakdown characteristics”, U.S. Pat. No. 5,998,833, granted on Dec. 7, 1999, by Baliga, hereinafter referred to as U.S. Pat. No. 5,998,833.
   The power semiconductor device has improved high frequency switching and breakdown characteristics. A unit cell 200 of a preferred integrated power semiconductor device has a predetermined width “W_{c}” (e.g., 1 μm) and comprises a highly doped drain layer 114 of first conductivity type (e.g., N+), a drift layer 112 of first conductivity type having a linearly graded doping concentration therein, a relatively thin base layer 116 of second conductivity type (e.g., P-type) and a highly doped source layer 118 of first conductivity type (e.g., N+). A source electrode 128b and drain electrode 130 may also be provided at the first and second faces, in ohmic contact with the source layer 118 and drain layer 114, respectively. The drift layer 112 may be formed by epitaxially growing an N-type in-situ doped monocrystalline silicon layer having a thickness of about 4 μm on an N-type drain layer 114 (e.g., N+ substrate) having a thickness of 100 μm and a first conductivity type doping concentration of greater than about 1×10¹⁸ cm⁻³ (e.g. 1×10¹⁹ cm⁻³) therein. As illustrated, the drift layer 112 may have a linearly graded doping concentration therein with a maximum concentration of greater than about 5×10¹⁶ cm⁻³ (e.g., 3×10¹⁷ cm⁻³ at the N+/N non-rectifying junction with the drain layer 114 and a minimum concentration of 1×10¹⁶ cm⁻³ at a depth of 1 μm and continuing at a uniform level to the upper face. The base layer 116 may be formed by implanting P-type dopants such as boron into the drift layer 112 at an energy of 100 kEV and at a dose level of 1×10¹⁴ cm⁻², for example. The P-type dopants may then be diffused to a depth of 0.5 μm into the drift layer 112. An N-type dopant such as arsenic may then be implanted at an energy of 50 kEV and at dose level of 1×10¹⁵ cm⁻². The N-type and P-type dopants are then diffused simultaneously to a depth of 0.5 μm and 1.0 μm, respectively, to form a composite semiconductor substrate containing the drain, drift, base and source layers. As illustrated by FIG. 2, the first conductivity type (e.g., N-type) doping concentration in the drift layer 112 is preferably less than about 5×10¹⁶ cm⁻³ at the P-N junction with the base layer 116 (i.e., second P-N junction), and more preferably only about 1×10¹⁶ cm⁻³ at the P-N junction with the base layer 116. The second conductivity type (e.g., P-type) doping concentration in the base layer 116 is also preferably greater than about 5×10¹⁶ cm⁻³ at the P-N junction with the source layer 118 (i.e., first P-N junction). Furthermore, the second conductivity type doping concentration in the base layer 116 at the first P-N junction (e.g., 1×10¹⁷ cm⁻³) is about ten times greater than the first conductivity type doping concentration in the drift region at the second P-N junction (e.g., 1×10¹⁶ cm⁻³). A stripe-shaped trench having a pair of opposing sidewalls 120a which extend in a third dimension (not shown) and a bottom 120b is then formed in the substrate. For the unit cell 200 having a width W_{c} of 1 μm, the trench is preferably formed to have a width “Wₜ” of 0.5 μm at the end of processing. A gate electrode/source electrode insulating region 125, a gate electrode 127 (e.g., polysilicon) and a trench-based source electrode 128a (e.g., polysilicon) are also formed in the trench. Because the gate electrode 127 is made relatively small and does not occupy the entire trench, the amount of gate charge required to drive the unit cell 200 during switching is accordingly small. While the U.S. Pat. No. 5,998,833 claims improved high frequency switching and breakdown characteristics, it is noted that the requirement of a drift layer 112 having a linearly graded epitaxial doping concentration poses significant challenge of manufacturing quality control and tends to increase device manufacturing cost.

As a third example, FIG. 3 illustrates a trenched MOSFET device with split gate and thick oxide layer on the trench bottom, fabricated using high-density plasma (HDP) deposited source-body implant block, from US 20080265289. A plurality of trenches 208 are opened into an epitaxial layer 210, having a uniform doping concentration, supported on a semiconductor substrate 205. Then an HDP deposition of oxide layer is applied to form a thick oxide layer 215 at the trench bottom and thinner oxide layer and thicker oxide layer 220 on the top surface of the substrate. A deposition of first polysilicon gate and etch back of the polysilicon is carried out to form the bottom segment of the gate 225 at the bottom portion of the trenches 208. A second HDP deposited oxide layer is carried out to deposit a second oxide layer 230 on top of the first HDP oxide layer 215 and the first gate segment 225. An oxide etch is carried out to etch out part of the oxide layers 230 and the upper portion of thinner oxide surrounding the sidewalls of the trench 208. The oxide etch also removes the second HDP layer 230 and a part of the thick oxide layer 220 near the trenches 208 and leaving only thick oxide layer 220 in the mesa area and the thick second HDP oxide layer 230 on top of the bottom gate segment. The split gate is formed by a depositing a second polysilicon layer 240 followed by a polysilicon etch back to form the upper gate segment 240 on top of the inter-poly insulation layer 230 formed by the second HDP oxide deposition process. Notice that the first gate segment 225 is narrower than the second gate segment 240. Furthermore, the width of the first gate segment 225 also tapers down toward the epitaxial layer 210 resulting in an increased gate oxide thickness near the drain electrode. To those skilled in the art this will beneficially cause a reduced gate-to-drain capacitance.

As a fourth example, FIG. 4 illustrates the cross-sectional view of an n-channel trench DMOS cell from U.S. Pat. No. 6,262,453. The DMOS device 100 includes a champagne-glass shaped trenched gate padded by a double-gate-oxide structure having a buried high-dopant-concentration region underneath. The DMOS transistor 100 is formed on a N+ substrate 105 supporting an N epitaxial layer 110 thereon having a uniform doping concentration. The DMOS transistor 100 includes a plurality of cell in the core cell area. Each cell includes a trenched gate 125 with the trench bottom surface lying above the N+ substrate. An N+ source region 140 and a P-body region 130 surround the trenched gate 125. The P-body region 130 is formed to have a less depth than that of the trenched gates 125. A body implant has been performed through the contact openings to form numerous high-concentration body-dopant regions 160 to reduce the contact resistance. Each of the trenched gates 125 of this invention is a champagne-glass shaped trenched gate padded by a double-gate-oxide structure, or graded gate oxide thickness, from the source and body regions. The double-gate-oxide structure includes a thick-gate-oxide layer 120′ covering the trench walls on the bottom portion of the trench. The double-gate-oxide structure further includes a thin-gate-oxide layer 120 covering the trench walls on the upper portion of the trench which has a layer thickness about one-fourth to one half the thickness of the thick-gate-oxide layer. The breakdown voltage over this thick-gate-oxide layer i.e., BVox, is greater than the drain-to-source breakdown voltage, i.e., BVds. Therefore, with a double-gate-oxide structure, an early breakdown that usually occurs at the bottom of the trenched gate 125 is prevented because it is now padded with thick-gate-oxide layer 120′. Also, an increase in threshold due to a thicker gate-oxide 120′ is also prevented because the upper portion of the trenched gate is padded with a thin-gate-oxide layer 120. The DMOS transistor 100 further has a high-dopant-concentration N+ buried region 118 formed below the bottom of the champagne-glass shaped trenched gate 125. The N+ buried region 118 formed in the N-epitaxial layer 110 provides a benefit of reducing the drain-to-source resistance R_{ds}. There is no significant increase of the drain-to-gate capacitance by introducing the N+ buried-region 118 because the dopant concentration near the bottom of the trenched gate 125 is not significantly increased. To complete the top portion of the DMOS device 100, an insulation layer 145 is deposited over the entire surface. Afterwards, a metal layer 170 is deposited over the insulation layer 145 to contact the source regions 140 via the contact openings.

In view of the foregoing background arts, a primary objective of the present invention is focused on simplified fabrication method for making trenched MOSFET devices with simple gate-oxide structure while still exhibiting reduced gate-to-drain capacitance.

### BRIEF DESCRIPTION OF THE DRAWINGS

In order to more fully describe numerous embodiments of the present invention, reference is made to the accompanying drawings. However, these drawings are not to be considered limitations in the scope of the invention, but are merely illustrative.

FIG. 1 illustrates a first prior art MOSFET device including a shielded gate trench (SGT) structure of U.S. Pat. No. 7,633,119;

FIG. 2 illustrates a second prior art power semiconductor device having improved high frequency switching and breakdown characteristics of U.S. Pat. No. 5,998,833;

FIG. 3 illustrates a third prior art trenched MOSFET device with split gate and thick oxide layer on the trench bottom of US 20080265289;

FIG. 4 illustrates a fourth prior art of a trench DMOS device including a champagne-glass shaped trenched gate padded by a double-gate-oxide structure having a buried high-dopant-concentration region underneath of U.S. Pat. No. 6,262,453;

FIG. 5 illustrates a key portion of the gate structure of a trenched DMOS device with step-graded gate-oxide thickness for reduced gate-to-drain capacitance under the present invention;

FIG. 6A through FIG. 6J illustrate, under the present invention, the fabrication method for making the key portion of the gate structure of FIG. 5; and

FIG. 6K through FIG. 6L illustrate, under the present invention, the additional fabrication steps following FIG. 6J for completing the DMOS device.

### DETAILED DESCRIPTION OF SPECIFIC EMBODIMENTS

The description above and below plus the drawings contained herein merely focus on one or more currently preferred embodiments of the present invention and also describe some exemplary optional features and/or alternative embodiments. The description and drawings are presented for the purpose of illustration and, as such, are not limitations of the present invention. Thus, those of ordinary skill in the art would readily recognize variations, modifications, and alternatives. Such variations, modifications and alternatives should be understood to be also within the scope of the present invention.

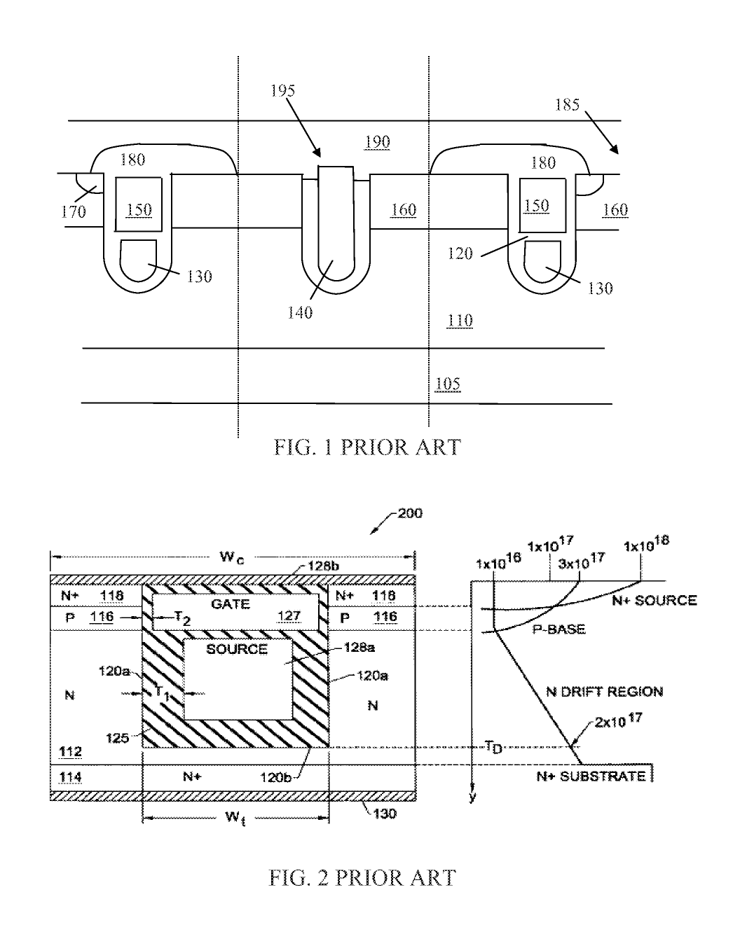

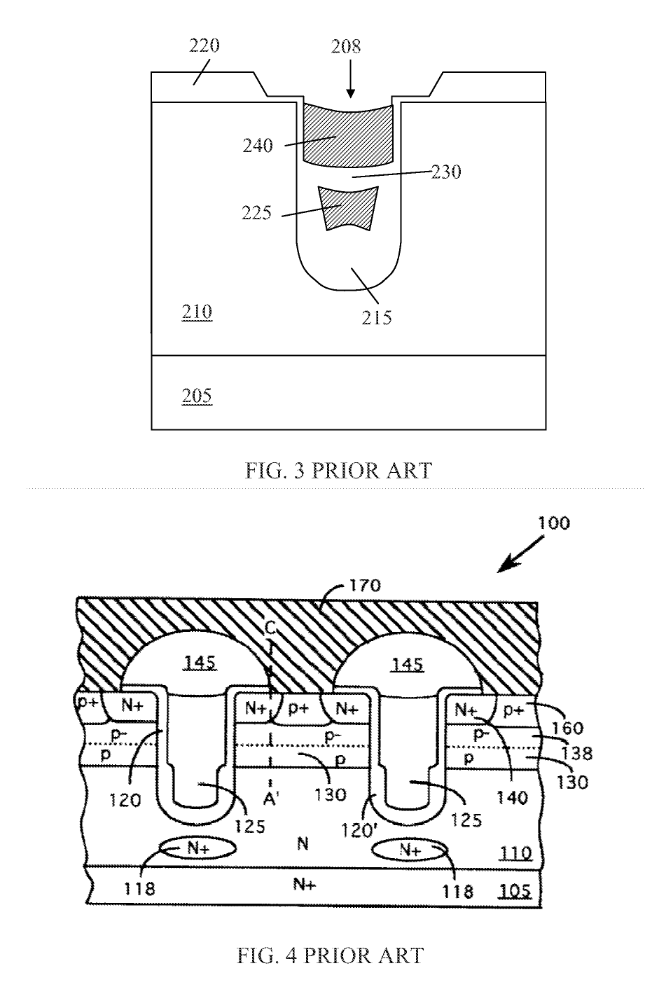

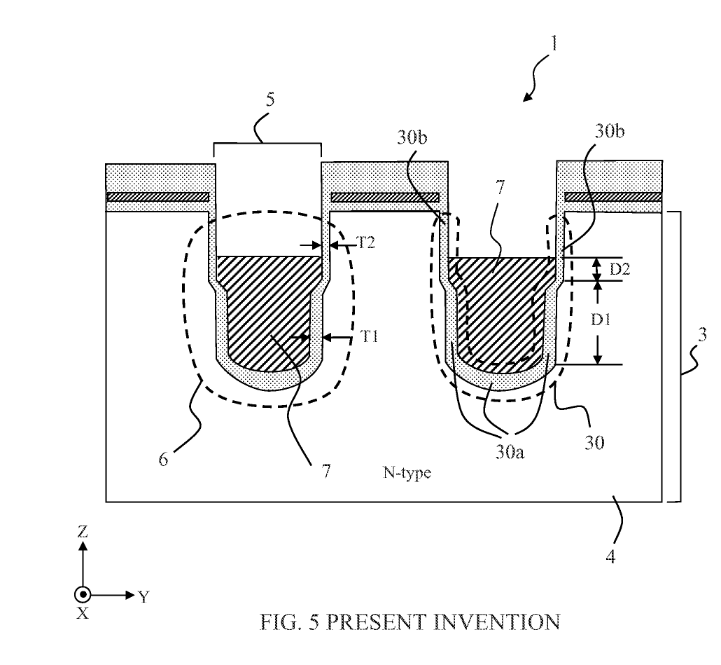

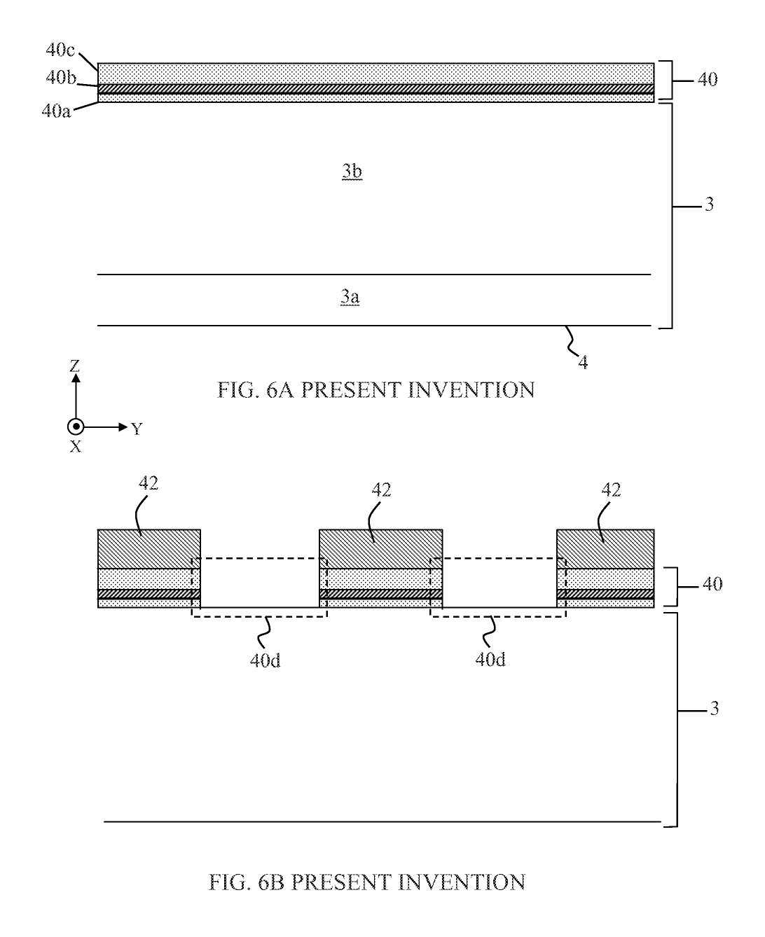

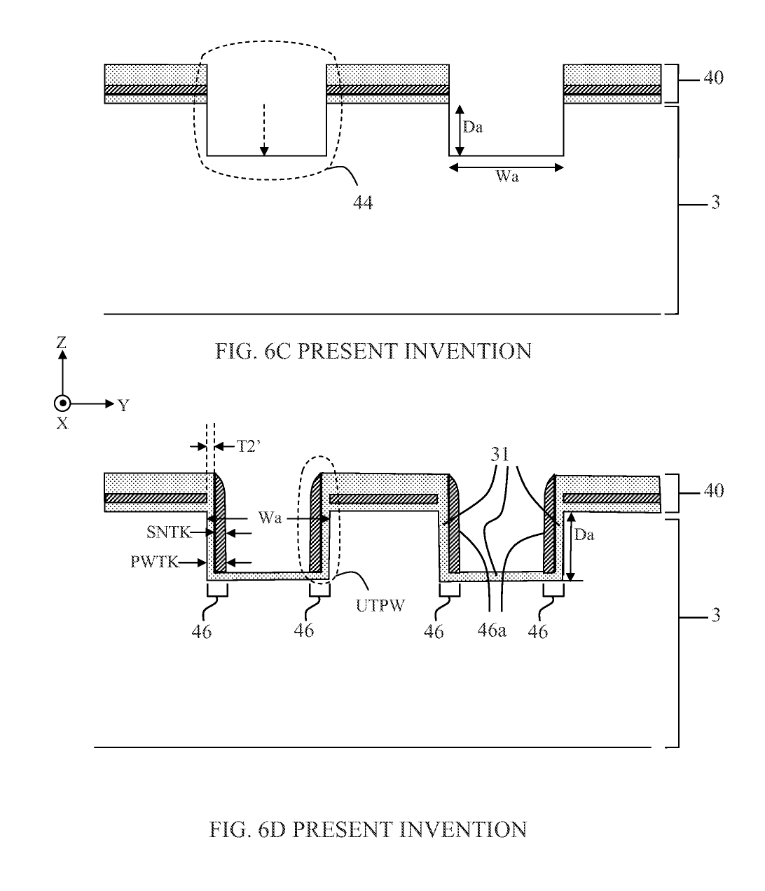

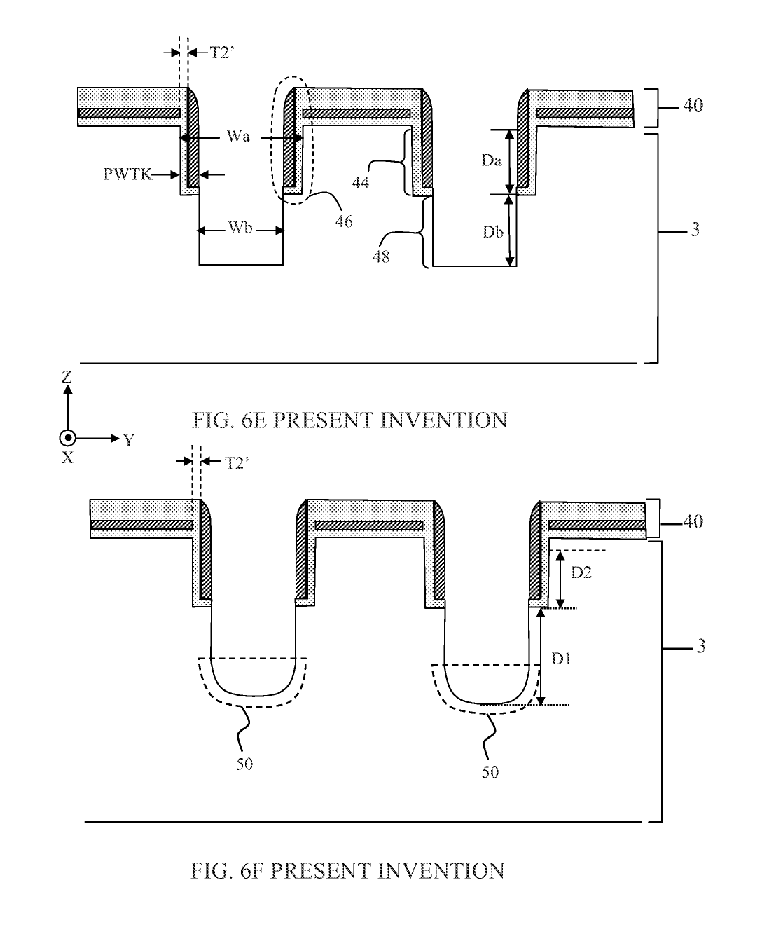

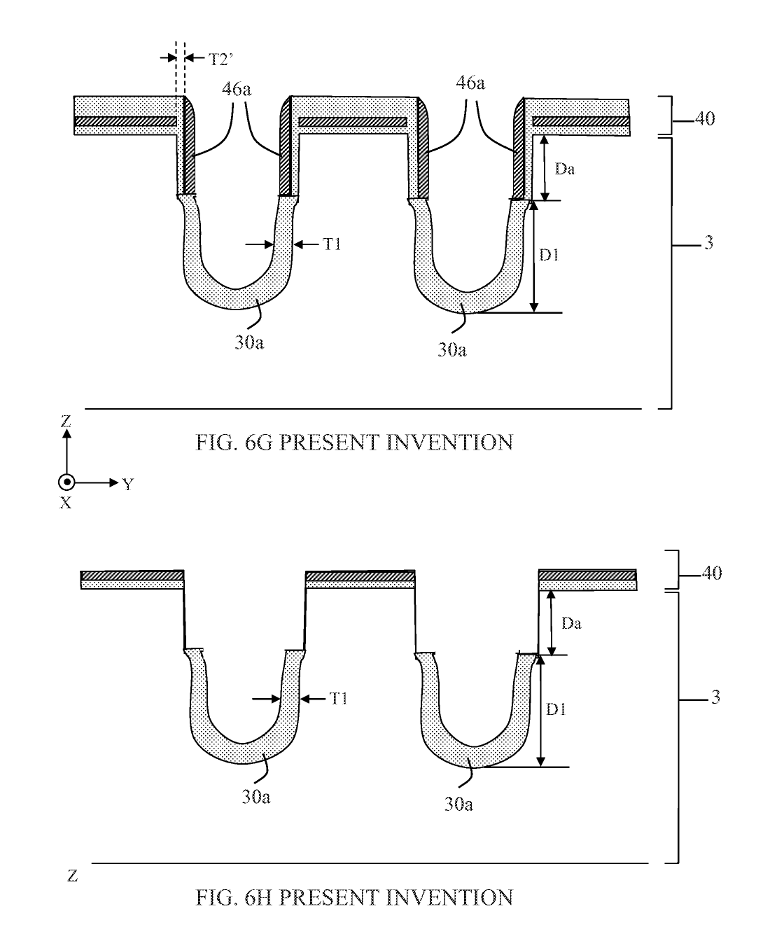

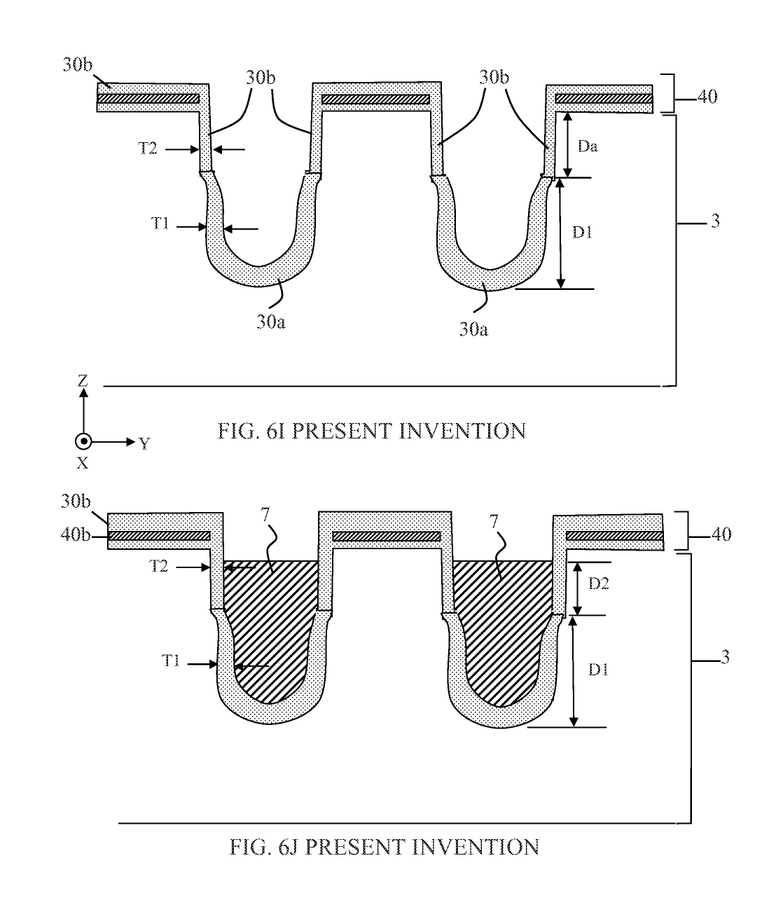

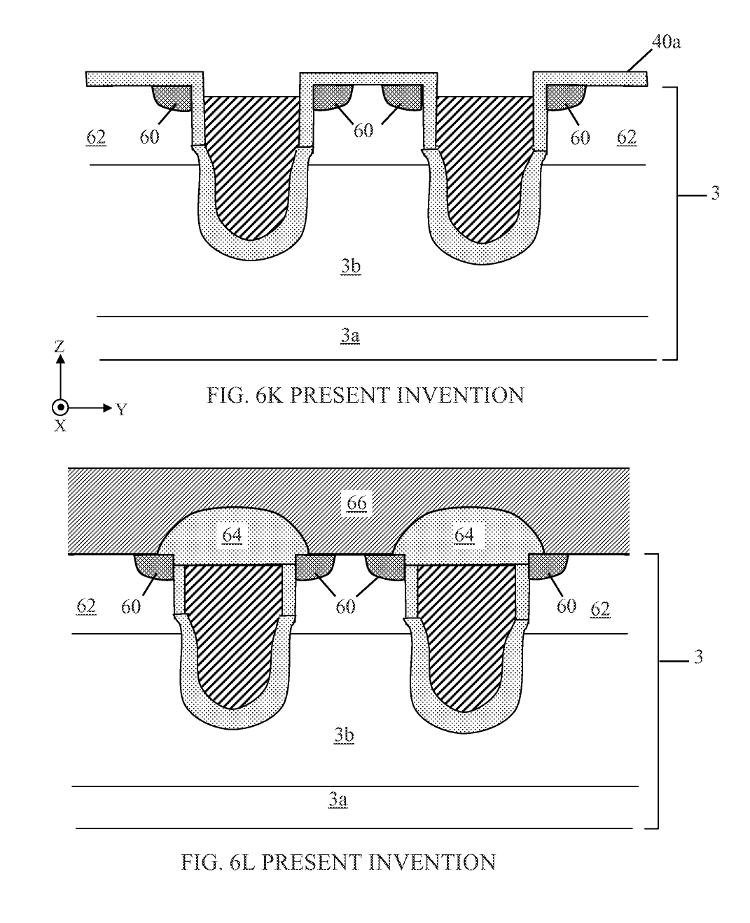

FIG. 5 illustrates a key portion of trenched DMOS device 1 with step-graded gate-oxide thickness for reduced gate-to-drain capacitance under the present invention. The portion of trenched DMOS device 1 is supported on a substrate 3 of a first conductivity type (in this case N-type). For convenience of description, an X-Y-Z Cartesian coordinates with X-Y plane parallel to the major substrate plane and Z-axis pointing upwards is adopted. The portion of trenched DMOS device 1 has:
A drain contact 4 disposed at a bottom surface of the substrate 3.
A gate 6 disposed in a trench 5 opened from a top surface of the substrate 3 including a pre-formed N-type epitaxial layer 3b that is a uniformly doped epitaxial layer (see FIG. 6A). Notably, the gate 6 has a polysilicon trench-filling layer 7 that fills the trench 5. The polysilicon trench-filling layer 7 is padded by a gate-oxide with step-graded thickness (S-G GOX) 30. The S-G GOX 30 includes a thick-oxide-layer 30a of thickness T1 (X-Y plane), depth D1 (Z-axis). The thick-oxide-layer 30a covers a lower portion of the trench walls. The S-G GOX 30 also includes a thin-gate-oxide 30b of thickness T2 (X-Y plane), depth D2 (Z-axis) with T2<T1. The thin-gate-oxide 30b covers an upper portion of the trench walls.
   To those skilled in the art the presence of the thick-oxide-layer 30a contributes to a corresponding beneficial reduction of gate-to-drain capacitance. To avoid excessive obscuring details gate metals contacting the gate 6, top device passivation and top metallization are not shown here. Thus, comparing with the structure of separated trenched gate 150 and bottom-shielding electrode 130 of U.S. Pat. No. 7,633,119 (FIG. 1) the present invention device structure is simpler with its single piece polysilicon trench-filling layer 7. Next, comparing with the drift layer 112 having a linearly graded doping concentration of U.S. Pat. No. 5,998,833 (FIG. 2) the present invention device structure is also simpler with its drift layer, although not shown here, having a uniform doping concentration. Likewise, comparing with the split gate device (gate segments 240 and 225) of US 20080265289 (FIG. 3) the present invention device structure is simpler with its single piece polysilicon trench-filling layer 7. While the champagne-glass shaped trenched gate padded by a double-gate-oxide structure (125, 120, 120′ of FIG. 4) of U.S. Pat. No. 6,262,453 does resemble a corresponding gate structure 6 of the present invention, the overall present invention device structure is still notably simpler with its absence of the high-dopant-concentration N+ buried region 118 formed below the bottom of the champagne-glass shaped trenched gate 125 of U.S. Pat. No. 6,262,453. Therefore, the fabricate method of the present invention device, to be presently described, can be correspondingly simpler than the cited numerous prior arts.

FIG. 6A through FIG. 6J illustrate, under the present invention, the fabrication method for making the key portion of trenched DMOS device 1 of FIG. 5. In FIG. 6A a substrate 3 is provided with a drain contact 4 at its bottom, a pre-formed highly doped N-type drain layer 3a and a pre-formed N-type epitaxial layer 3b having a uniform doping concentration at its top. Next, a silicon oxide-silicon nitride-silicon oxide (ONO) protective composite layer 40, having a silicon oxide protective sub-layer 40a, a silicon nitride protective sub-layer 40b and a silicon oxide protective sub-layer 40c, is then formed atop the substrate 3. This can be carried out by successively forming the silicon oxide protective sub-layer 40a, the silicon nitride protective sub-layer 40b and the silicon oxide protective sub-layer 40c.

FIG. 6B through FIG. 6E illustrate the creation, into the substrate 3, an upper interim trench (UIT) 44, an upper trench protection wall (UTPW) 46 and a lower interim trench (LIT) 48.

In FIG. 6B a trench mask 42 is formed then patterned, according to a desired top cross sectional geometry (X-Y plane) of the trench 5, atop the ONO composite layer 40. A number of ONO trenches 40d are then created by masked anisotropical etching through the ONO composite layer 40.

In FIG. 6C the masked anisotropical etching is continued until it created the UIT 44 with a cross sectional width Wa (X-Y plane) and depth Da (Z-axis) partially into the substrate 3 where Da>D2.

In FIG. 6D a thin oxide 31, of thickness T2′, is deposited atop the device in progress followed by the formation of a sacrificial nitride spacer layer (SNSL) 46a, of thickness SNTK, covering only the vertical side surfaces of the UIT 44 thus completing the UTPW 46 of thickness PWTK. In more detail, a nitride layer is first deposited atop the device in progress thus covering the sidewalls and bottom of the trench 5, then the portions of the nitride layer covering the horizontal surfaces of the thin-gate-oxide 30b and atop the ONO composite layer 40 are etched away with a wet etch. Notice that the resulting UTPW 46 is a bi-layer with PWTK=T2′+SNTK.

In FIG. 6E all the unprotected thin oxide 31 (by the SNSL 46a) along the X-Y plane is first differentially etched away. Next, an anisotropical etching is carried out partially into the substrate 3 thus completing the lower interim trench LIT 48 that is butted beneath the UIT 44. Notice that the LIT 48 has a cross sectional width Wb and depth Db where Wb<Wa, Wb=Wa—2*PWTK and Db<D1.

FIG. 6F through FIG. 6H illustrate the steps of shaping and oxidizing the substrate 3 material surrounding the LIT 48 into a desired thick-oxide-layer 30a of thickness T1 then stripping off the SNSL 46a and thin oxide 31 and to create a thin-gate-oxide 30b of thickness T2. FIG. 6F illustrates an isotropical and partial etching of the exposed substrate 3 material surrounding the LIT 48 to deepen it with a rounded bottom floor 50.

FIG. 6G illustrates oxidization of the exposed substrate 3 material surrounding the LIT 48, with a LOCal Oxidation of Silicon (LOCOS) process, into the desired thick-oxide-layer 30a of thickness T1 and depth D1. For those skilled in the art, it should be understood that LOCOS is a microfabrication process where silicon dioxide gets formed in selected areas on a silicon wafer having a Si—SiO₂ interface at a lower point than the rest of the silicon surface. The LOCOS process automatically creates a smooth curved corner at the transition between the two thicknesses of oxide (that is, between thick-oxide-layer 30a and thin oxide 31) due to a well-known bird's beak effect. As a side remark, please note that a surface oxide cannot block the oxidation of silicon beneath it, only a surface nitride can.

In FIG. 6H the SNSL 46a is removed, which can be done by stripping it off with a wet etching process. Another wet etching process is then followed to remove the thin oxide 31 thus the substrate 3 material is exposed in UIT 44, which may reduce the thickness of the bottom LOCOS thick-oxide-layer 30a a little.

In FIG. 6I, a thin-gate-oxide 30b of a desired thickness T2 and depth Da is thus grown atop the device covering the exposed side surface of the UIT 44.

In FIG. 6J the UIT 44 and LIT 48 are filled with polysilicon via deposition. The deposited polysilicon is then etched back into a polysilicon trench-filling layer 7 till its top surface defines the desired depth D2 of thin-gate-oxide 30b, with D2<Da as shown.

FIG. 6K through FIG. 6L illustrate, under the present invention, the additional fabrication steps following FIG. 6J for completing the DMOS device, which is well known in the art. In FIG. 6K the thin oxide 30b and silicon nitride protective sub-layer 40b of the ONO composite layer 40 at the top of the substrate 3 can be successively etched away from the device in progress exposing the silicon oxide protective sub-layer 40a. A number of body regions 62 are formed, for example with ion implantation of P-type dopants, followed by forming a number of source regions 60, for example with ion implantation of N-type dopants at high concentration, at the top portion of the substrate 3 through the silicon oxide protective sub-layer 40a. In FIG. 6L the DMOS device is completed with the etching away of silicon oxide protective sub-layer 40a followed by successive deposition of device passivation regions 64 and contact metallization 66.

A simplified fabrication method has been proposed for making trenched MOSFET devices with simple gate-oxide structure while still exhibiting reduced gate-to-drain capacitance. While the description above contains many specificities, these specificities should not be construed as accordingly limiting the scope of the present invention but as merely providing illustrations of numerous presently preferred embodiments of this invention. Throughout the description and drawings, numerous exemplary embodiments were given with reference to specific configurations. It will be appreciated by those of ordinary skill in the art that the present invention can be embodied in numerous other specific forms and those of ordinary skill in the art would be able to practice such other embodiments without undue experimentation. For an example, with minor modification the simplified fabrication method of the present invention can be easily adapted to fabricate types of MOSFET devices other than the DMOS device, such as SGT MOSFET, split gate MOSFET and the likes. For another example, by simply repeating more fabrication steps as illustrated from FIG. 6D through FIG. 6E the present invention can be easily adapted to fabricate trenched DMOS Devices with MULTIPLE Step-Graded Thicknesses with no need for any more mask 42. The scope of the present invention, for the purpose of the present patent document, is hence not limited merely to the specific exemplary embodiments of the foregoing description, but rather is indicated by the following claims. Any and all modifications that come within the meaning and range of equivalents within the claims are intended to be considered as being embraced within the spirit and scope of the present invention.

We claim:

1. A method for making gate-oxide with step-graded thickness (S-G GOX) in a trenched DMOS device supported on a substrate of a first conductivity type (N) for reduced gate-to-drain capacitance, expressed in X-Y-Z Cartesian coordinates with X-Y plane parallel to the major substrate plane and Z-axis pointing upwards, the trenched DMOS device comprising:
a drain of first conductivity type disposed at a bottom surface of the substrate; a gate disposed in a trench opened from a top surface of the substrate, the gate having a polysilicon layer filling the trench padded by a gate-oxide layer with step-graded thickness (S-G GOX); the S-G GOX includes a thick-oxide-layer of thickness T1 (X-Y plane), depth D1 (Z-axis) and covering a lower portion of the trench walls plus a thin-gate-oxide of thickness T2 (X-Y plane), depth D2 (Z-axis) and covering an upper portion of the trench walls with T2<T1;
the method comprises:
a) providing the substrate and forming a silicon oxide-silicon nitride-silicon oxide (ONO) protective composite layer atop said substrate;
b) creating, into the substrate:
an upper interim trench (UIT) of cross sectional width Wa (X-Y plane) and depth Da (Z-axis) where Da>D2;
an upper trench protection wall (UTPW) of thickness PWTK covering the vertical surfaces of the UIT, the UTPW itself being a bi-layer comprising a thin oxide of thickness T2′ and a sacrificial nitride spacer layer (SNSL) of thickness SNTK such that T2′+SNSL=PWTK; and
a lower interim trench (LIT), butted beneath the UIT, said LIT being of cross sectional width Wb and depth Db where Wb<Wa, Wb=Wa−2*PWTK and Db<D1;
c) shaping and oxidizing the substrate material surrounding the LIT into the desired thick-oxide-layer of thickness T1, depth D1 and stripping off the SNSL and the thin oxide to expose the substrate material at the vertical surface of the UIT;
d) forming a thin-gate-oxide of thickness T2 on the vertical surfaces of the UIT; and
e) filling the UIT and LIT with polysilicon then etching it back into a polysilicon layer till its top surface defines the desired thin-gate-oxide depth D2.

2. The method of claim 1 wherein creating the UIT, the UTPW and the LIT comprise:
b1) masking, through a trench mask shaped according to the top cross sectional geometry (X-Y plane) of the trench;
b2) etching completely through the ONO composite layer followed by etching anisotropically but partially into the substrate to create the UIT;
b3) depositing the thin oxide atop the device in progress and forming the SNSL covering only the vertical surfaces of the UIT whereby completing the UTPW; and
b4) differentially etching away all the unprotected, by the SNSL and thin oxide, along the X-Y plane then anisotropically and partially etching into the substrate to complete the LIT.

3. The method of claim 2 wherein forming the SNSL covering only the vertical surfaces of the UIT comprises depositing a nitride spacer layer atop the device in progress then anisotropically etching away portions of the nitride spacer layer covering the horizontal surfaces of the thin oxide.

4. The method of claim 1 wherein shaping and oxidizing the substrate material comprise:
isotropically and partially etching the exposed substrate material surrounding the LIT to deepen the LIT with a rounded bottom floor; and
oxidizing the exposed substrate material surrounding the LIT, with a local oxidation of silicon LOCOS) process, into the desired thick-oxide-layer of thickness T1 and depth D1.

5. The method of claim 1 wherein providing the substrate comprises providing a substrate with a pre-formed drain layer of a first conductivity type (N) and a pre-formed uniform doping epitaxial layer of a first conductivity type (N) thereon, wherein the doping concentration of the drain layer is higher than that of the epitaxial layer.

6. The method of claim 1 further comprises:
e) forming body regions, source regions, device passivation regions and contact metallization atop the device in progress whereby completing the DMOS device.
